(19) United States
(12) Patent Application Publication
(10) Pub. No.: US 2013/0119975 A1
(43) Pub. Date: May 16, 2013

(54) CURRENT DETECTOR

(71) Applicants: Hirokatsu Nakajima, Yokkaichi (JP); Satoru Chaen, Yokkaichi (JP)

(72) Inventors: Hirokatsu Nakajima, Yokkaichi (JP); Satoru Chaen, Yokkaichi (JP)

(73) Assignee: SUMITOMO WIRING SYSTEMS, LIMITED, Yokkaichi-city, Mie (JP)

(21) Appl. No.: 13/810,578

(22) PCT Filed: Feb. 7, 2011
(86) PCT No.: PCT/JP2011/052517

§ 371 Date: Jan. 16, 2013

(30) Foreign Application Priority Data
Aug. 23, 2010 (JP) 2010-185980

(51) Int. Cl. G01R 19/20

(52) U.S. Cl. CPC G01R 19/20
USPC 324/117 R

(57) ABSTRACT

A current detector includes an electronic circuit board on which a circuit for processing a detection signal of a Hall element disposed in a gap portion of a magnetic core is mounted, and a spring member such as a coil spring that is made of a conductor electrically connected to a ground pattern on the electronic circuit board, and that is supported on the electronic circuit board and is in contact with the magnetic core. The magnetic core, a busbar for current detection, and the electronic circuit board on which the Hall element is mounted are held in a fixed positional relationship by an insulating casing.

The exemplary embodiments relate to a current detector for detecting a current that flows through a busbar.

### BACKGROUND

Vehicles such as hybrid automobiles or electric automobiles in many cases include a current detector for detecting a current that flows through a busbar connected to a battery. Examples of apparatuses that may be applied as such a current detector include a magnetic proportion-type current detector and a magnetic balance-type current detector.

A current detector of a magnetic proportion type or a magnetic balance type includes a magnetic core and a magneto-electric conversion element (magnetic induction element), for example, as shown in JP-A-2009-128116. The magnetic core is a magnetic material substantially in the shape of a ring with a gap portion, resulting in two ends facing each other across the gap portion, and formed in one piece so as to surround a hole portion through which a busbar penetrates. The hole portion of the magnetic material is a space (current detection space) through which a current that is to be detected flows.

Furthermore, the magneto-electric conversion element is disposed in the gap portion of the magnetic core. The magneto-electric conversion element is an element that detects changes in the magnetic flux of a current that flows through the busbar penetrating through the hole portion, and then outputs a detection signal of the magnetic flux as an electrical signal. A Hall element is typically used as the magneto-electric conversion element.

As shown in JP-A-2009-128116, in conventional current detectors, the magnetic core, the busbar, and the magneto-electric conversion element are in many cases held in a fixed positional relationship by an insulating casing. A plurality of components forming the current detector are positioned in a fixed positional relationship by this casing.

When a high voltage is generated in the busbar due to a static electrical charge or the like, the high voltage may flow from the busbar and damage electronic components including the magneto-electric conversion element that is disposed close to the busbar and components that are electrically connected to the magneto-electric conversion element. In the current detector, the insulating casing provides isolation between the busbar and the magneto-electric conversion element, and also functions as an electrically shielding material that improves electrical insulation between the busbar and the electronic components including the magneto-electric conversion element. This function prevents the electronic components including the magneto-electric conversion element from being damaged by a high voltage flowing from the busbar.

### SUMMARY

There is an increasing demand for reducing the size of current detectors that are fitted in vehicles. Accordingly, it is difficult to ensure a space for allowing an insulating member to electrically shield the magneto-electric conversion element from the busbar. That is to say, conventional current detectors are problematic in that it is difficult to both prevent electronic components from being damaged by a high voltage flowing from the busbar, and reduce the size of the current detector.

It is an object of the exemplary embodiments to provide a current detector for detecting a current that flows through a busbar, in which it is possible to both prevent electronic components from being damaged by a high voltage flowing from the busbar, and reduce the size of the current detector.

A current detector according to the exemplary embodiments includes the following:

(1) a magnetic core that has both of two ends thereof facing each other across a gap portion and that is formed in one piece so as to surround a hole portion through which a busbar allowing a current to flow therethrough penetrates;

(2) a magneto-electric conversion element disposed in the gap portion and that detects changes in the magnetic flux of a current that flows through the hole portion;

(3) an electronic circuit board on which a circuit for processing a detection signal of the magneto-electric conversion element is mounted; and

(4) a spring member that is made of a conductor electrically connected to a ground pattern on the electronic circuit board, and that is supported on the electronic circuit board and is in contact with the magnetic core.

Furthermore, in the current detector according to the exemplary embodiments, the busbar for current detection may further include the following:

(5) a casing made of an insulating member that holds, in a fixed positional relationship, the magnetic core, the busbar, and the electronic circuit board on which the magneto-electric conversion element is mounted, in a state where the spring member elastically biases the magnetic core.

In the current detector according to the exemplary embodiments, it is preferable that the spring member is a coil spring having one end fixed to the electronic circuit board.

Furthermore, in the current detector according to the exemplary embodiments, if the spring member is a coil spring, it is preferable that the electronic circuit board and the casing have a through-hole in connection with an internal space of the coil spring through the electronic circuit board. Furthermore, a protruding portion in a shape of a rod that penetrates through the through-hole of the electronic circuit board and extends into the internal space of the coil spring may be formed on the casing.

In the current detector according to the exemplary embodiments, the magnetic core that is disposed closest to the busbar for current detection may be electrically connected via the spring member to the ground pattern. The ground pattern on the electronic circuit board may be electrically connected to a ground conductor such as a vehicle body, via an electrical wire connected to the connector, for example. Accordingly, when a high voltage is generated in the busbar, due to a static electrical charge or the like, the high-voltage electricity flows from the busbar via the magnetic core, the spring member, and the ground pattern on the electronic circuit board to the ground conductor such as the vehicle body. Furthermore, a surge suppression circuit such as a surge absorber is typically mounted on the electronic circuit board in order to suppress surges between the electronic components and the ground pattern.

Thus, according to the exemplary embodiments, it is possible to prevent electronic components from being damaged by a high voltage flowing from the busbar. Furthermore, according to the exemplary embodiments, since there is no need to ensure a large space for allowing an insulating member to electrically shield the magneto-electric conversion element from the busbar, it is possible to reduce the size of the current detector.

Examples of a mode for electrically connecting the magnetic core and the ground conductor such as a vehicle body may also include a first connection mode and a second connection mode described below. The first connection mode is a mode in which the magnetic core and the ground pattern on the electronic circuit board are in direct contact with each other. The second connection mode is a mode in which an electrical conductor electrically connected to the ground conductor is connected to the magnetic core by welding, screwing, or the like. The first connection mode may be problematic in that the contact state between the magnetic core and the ground pattern on the electronic circuit board may not be stable depending on dimensional tolerance. The second connection mode may be problematic in that the thermal load or physical load that acts on the magnetic core is large, and this load adversely affects the current detection performance.

According to the exemplary embodiments, since the spring member that electrically connects the magnetic core and the ground pattern on the electronic circuit board is elastically deflected, the electrical contact state between the magnetic core and the ground pattern on the electronic circuit board is stable, and the physical load that acts on the magnetic core can be made small.

Further, according to the current detector according to the exemplary embodiments, since the magnetic core, the busbar, and the electronic circuit board may be positioned in a fixed relationship by the casing, the current detector can be easily attached to other pre-installed busbars.

Furthermore, when the spring member is a coil spring having one end fixed to the electronic circuit board, the force of the spring member that elastically biases the magnetic core is more stable than when another type of spring member such as a leaf spring is used, and, thus, the electrical connection state between the magnetic core and the ground pattern on the electronic circuit board tends to be more stable.

Furthermore, in the exemplary embodiments, when a protruding portion in a shape of a rod that penetrates through the through-hole of the electronic circuit board and extends into the internal space of the coil spring is formed on the casing, the protruding portion keeps the coil spring from being deflected (bent) in the width direction orthogonal to the axial direction, thereby making the coil spring compressible and stretchable mainly in the axial direction. As a result, a failure in contact with the magnetic core due to excessive deflection of the coil spring in the width direction is prevented from occurring.

### BRIEF DESCRIPTION OF THE DRAWINGS

FIG. 1 shows an exploded perspective view of a current detector according to an embodiment of the present invention;

FIGS. 2A, 2B and 2C show views of three sides of a busbar for current detection included in the current detector;

FIG. 3 shows a plan view of a component for forming the busbar for current detection;

FIG. 4 shows a plan view of the current detector;

FIG. 5 shows a cross-sectional view of the current detector; and

FIG. 6 shows a schematic perspective view of a state in which the current detector is joined with pre-installed busbars.

### DETAILED DESCRIPTION OF THE EMBODIMENTS

Referring now to the drawings, exemplary embodiments will be described with reference to the drawings. The following exemplary embodiments are merely exemplary, and do not to restrict the technical scope of the invention.

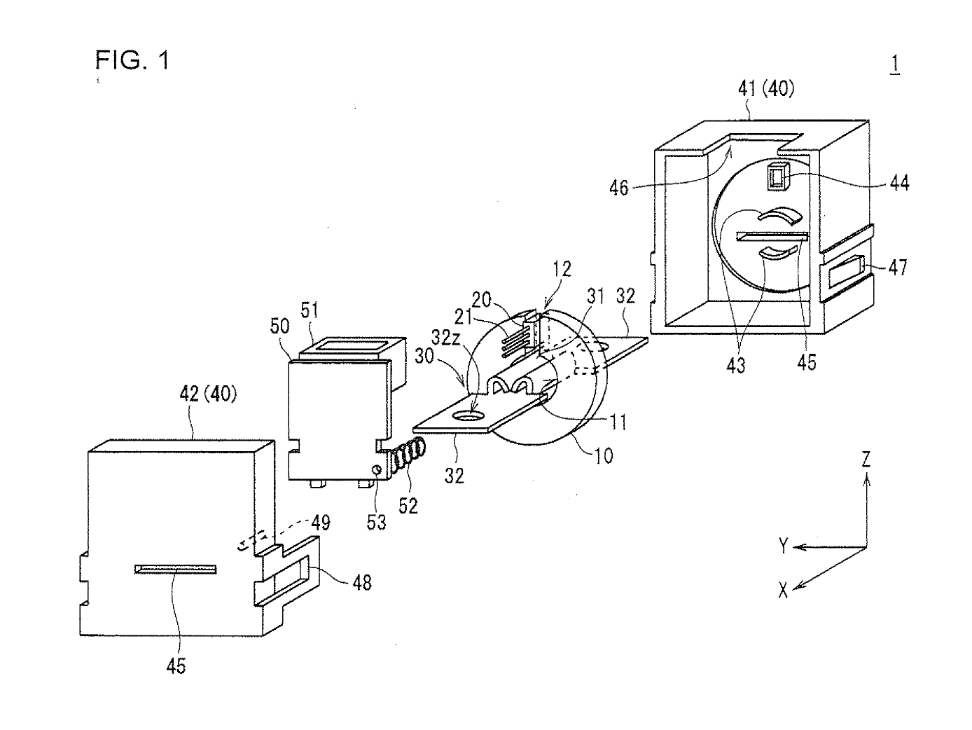

First, the configuration of a current detector 1 according to an exemplary embodiments will be described with reference to FIGS. 1 to 5. The current detector 1 is an apparatus for detecting a current that flows through a busbar electrically connecting a battery and a device such as a motor, in vehicles such as hybrid automobiles or electric automobiles. As shown in FIG. 1, the current detector 1 may include a magnetic core 10, a Hall element 20, a busbar 30 for current detection, an insulating casing 40, an electronic circuit board 50, and a coil spring 52 that is supported on the electronic circuit board 50.

The magnetic core 10 is a magnetic material that may be made of, for example, ferrite or silicon steel, or the like. The magnetic core 10 may be formed into one piece, having two ends, with both of its two ends facing each other across a gap portion 12, so as to surround a hole portion 11. The gap portion 12 is approximately several millimeters. The magnetic core 10 is substantially in the shape of a continuous loop with a gap portion 12. The magnetic core 10 in this embodiment is substantially in the shape of a ring that surrounds the circular hole portion 11.

The Hall element 20 is disposed in the gap portion 12 of the magnetic core 10. The Hall element 20 is an example of a magneto-electric conversion element for detecting changes in the magnetic flux of a current that flows through the hole portion 11 of the magnetic core 10, and then outputting a detection signal of the magnetic flux as an electrical signal.

The electronic circuit board 50 may be a printed circuit board on which a terminal 21 of the Hall element 20 is mounted. In addition to the Hall element 20, a circuit that amplifies the detection signal of the magnetic flux output from the Hall element 20, and a connector 51 that connects this circuit and another external circuit may be mounted on the electronic circuit board 50. Accordingly, the connector 51 is electrically connected to the Hall element 20, and the Hall element 20 is connected, via the electronic circuit board 50 including the connector 51, to the external circuit. Furthermore, the connector 51 may include a ground terminal that is electrically connected to a ground pattern on the electronic circuit board 50. The ground pattern on the electronic circuit board 50 may be electrically connected to a ground conductor such as a vehicle body, via the ground terminal of the connector 51 and a grounding electrical wire that may be connected to the ground terminal.

Furthermore, a surge suppression circuit may be mounted on the electronic circuit board 50. The surge suppression circuit may be an element or a circuit such as a surge absorber or an RC circuit mounted in order to suppress surges between the Hall element 20 and other electronic components that are mounted on the electronic circuit board 50 and the ground pattern printed on the electronic circuit board 50. The surge suppression circuit blocks propagation of a noise voltage to electronic components that are mounted on the electronic circuit board 50, when a noise voltage such as pulse-like high voltage is generated on the ground pattern on the electronic circuit board 50.

The coil spring 52 may be a member made of a conductor such as copper, aluminum, or stainless steel, shaped into a coil, and electrically connected to the ground pattern on the electronic circuit board 50. The coil spring 52 preferably is elastically compressed, and has one end fixed to the electronic circuit board 50 and the other end in contact with the magnetic core 10. For example, one end of the coil spring 52 may be soldered to the ground pattern on the electronic circuit board 50 or may be fitted to metal fittings mounted on the ground pattern on the electronic circuit board 50, and, thus, the coil spring 52 is fixed to the electronic circuit board 50.

Furthermore, in a portion of the electronic circuit board 50 to which the coil spring 52 is fixed, a through-hole 53 for the spring is fanned in connection with the internal space of the coil spring 52. The role of the through-hole 53 for the spring will be described later.

The busbar 30 for current detection may be a conductor made of a metal such as copper, and functions as part of a set of busbars electrically connecting a battery and an electrical device. A current that is to be detected flows through the busbar 30 for current detection. The busbar 30 for current detection may be a member independent of a battery-side busbar connected in advance with the battery and a device-side busbar connected in advance with the electrical device. Both ends of the busbar 30 for current detection may be respectively connected to the other pre-installed busbars (the battery-side busbar and the device-side busbar).

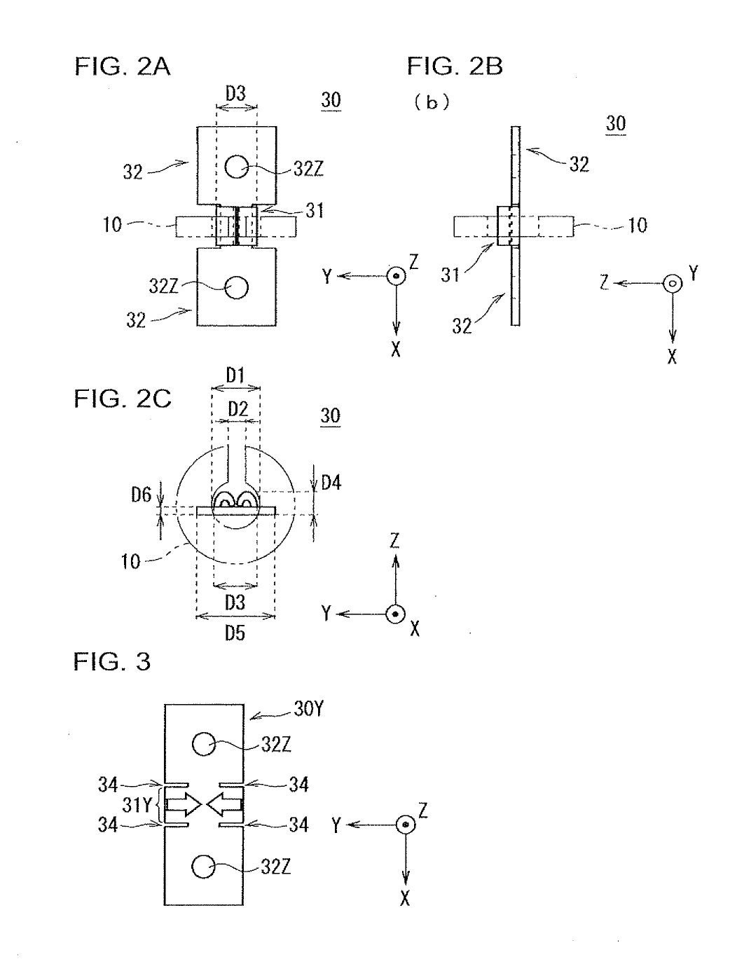

FIGS. 2A-2C shows views of three sides of the busbar 30 for current detection, wherein FIG. 2A is a plan view, FIG. 28 is a side view, and FIG. 2C is a front view. In FIG. 2, the magnetic core 10 combined with the busbar 30 for current detection is indicated by a broken line (double-dashed line).

As shown in FIGS. 1 and 2A-2C, the busbar 30 for current detection may be substantially configured by a first portion 31 that occupies a constant range at the center and second portions 32 that are located at both sides of the first portion 31. The first portion 31 may be a portion that penetrates through the hole portion 11 of the magnetic core 10 in the current flow direction. The current flow direction preferably is the thickness direction of the magnetic core 10, and is the axial direction of a cylinder when the magnetic core 10 is configured as a cylinder, and is the direction orthogonal to a plane formed by the ring-like magnetic core 10. In the drawings, the current flow direction is indicated as the X-axis direction. In the following description, the current flow direction (the X-axis direction) is referred to as a first direction.

The busbar 30 for current detection may be a member made of a conductor including the first portion 31 that penetrates through the hole portion 11 of the magnetic core 10 in the first direction and the second portions 32 that are in the shape of flat plates which may be connected to the first portion 31 on both sides in the first direction. In the drawings, the width direction and the thickness direction of the second portions 32 are respectively indicated as the Y-axis direction and the Z-axis direction. In the following description, the width direction (the Y-axis direction) and the thickness direction (the Z-axis direction) of the second portions 32 are respectively indicated as a second direction and a third direction.

As shown in FIG. 3, the busbar 30 for current detection is a member having a structure in which one portion 31Y of a metal member 30Y is folded back from both sides in the second direction (the Y-axis direction) along slits 34 that are formed on both sides of the portion 31Y in the first direction (the X-axis direction). The slits 34 in the metal member 30Y are formed on both sides of the portion 31Y in the first direction (the X-axis direction) so as to extend from both ends in the second direction (the Y-axis direction) to the inner side. The folded-back portion 31Y forms the first portion 31 of the busbar 30 for current detection, and portions on both sides of the portion 31Y form the second portions 32. This configuration of a busbar 30 for current detection facilitates easy manufacture.

In the busbar 30 for current detection, the contour shape of a cross-section of the first portion 31 preferably is narrower than that of the second portions 32 in the second direction (the Y-axis direction). As a result, when the busbar 30 for current detection is used in the current detector 1, a relatively small magnetic core 10 can be used based on the relationship with the width of the busbar 30, and, thus, the size of the entire current detector including the magnetic core 10 can be kept small.

Furthermore, in the busbar 30 for current detection, the contour shape of a cross-section of the first portion 31 preferably is such that a smallest width D4 is larger than a thickness (smallest width) D6 of the second portions 32. Accordingly, the conductor cross-sectional area at the first portion 31 is not significantly smaller than the conductor cross-sectional area at the second portions 32. Preferably, when the busbar 30 for current detection has a structure in which the metal member 30Y is partially folded back, the conductor cross-sectional area at the first portion 31 is equal to the conductor cross-sectional area at the second portions 32.

Preferably, portions of the busbar 30 for current detection where the slits 34 are formed between the first portion 31 and the second portions 32 each have a conductor cross-sectional area smaller than that of a portion located in front of or behind that portion. However, experiments found that, if the width of the slits 34 is very narrow, an increase in the impedance at the portions where the slits 34 are formed is a small value that is almost negligible in the entire busbar 30 for current detection. Accordingly, if the slits 34 formed in the busbar 30 for current detection each have a very narrow width, heat can be prevented from being excessively generated at the first portion 31.

Furthermore, the second portions 32 of the busbar 30 for current detection may respectively have screw holes 32Z into which screws for joining this busbar with other busbars are inserted. The second portions 32 in which the holes 32Z are formed function as terminal portions that are joined with other busbars.

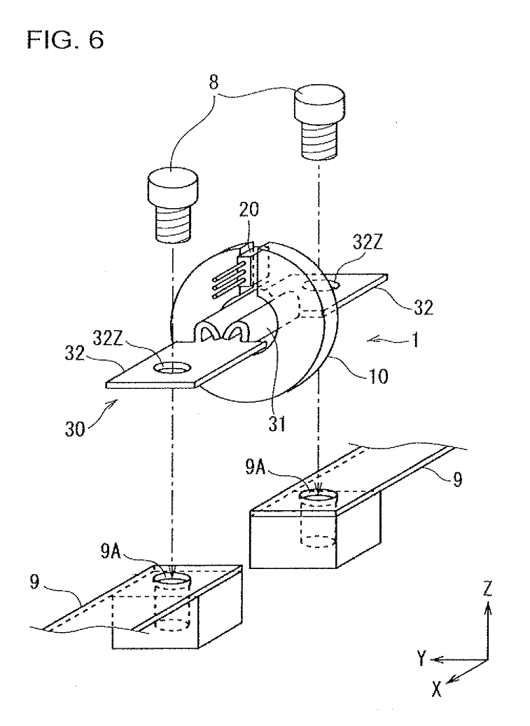

FIG. 6 is a perspective view schematically showing a state in which the second portions (the terminal portions) 32 of the busbar 30 for current detection in the current detector 1 are joined with other pre-installed busbars 9 via screws 8. In FIG. 6, the insulating casing 40 is not shown for the sake of convenience. As shown in FIG. 6, portions of the other busbars 9 that are joined with the second portions 32 of the busbar 30 for current detection are configured, for example, as terminal blocks, and have screw holes 9A. The terminal portions formed in the second portions 32 may be other than the screw holes 32Z, such as portions having fitting mechanisms to the other busbars 9.

The insulating casing 40 preferably is an insulating member that holds, in a fixed positional relationship, the magnetic core 10, the busbar 30 for current detection, and the electronic circuit board 50 on which the Hall element 20 has been mounted. The insulating casing 40 may include a casing main body 41 and a cover member 42 that preferably is attached to the casing main body 41. The casing main body 41 and the cover member 42 may be, for example, each a monolithic molded member made of insulating resin such as polyamide (PA), polypropylene (PP), or ABS resin.

The casing main body 41 may be in the shape of a box having an opening portion, and the cover member 42 may cover the opening portion of the casing main body 41 when attached to the casing main body 41. The internal face of the casing main body 41 preferably has first holding portions 43 and a second holding portion 44 that project out from the surface. On the casing main body 41, the first holding portions 43 and the second holding portion 44 may hold the magnetic core 10, the busbar 30 for current detection that penetrates through the hole portion 11, and the Hall element 20 disposed in the gap portion 12, while keeping them from coming into contact with each other.

The first holding portions 43 may be fitted into a gap between the magnetic core 10 and the first portion 31 of the busbar 30 for current detection that penetrates through the hole portion 11 of the magnetic core 10, thereby holding the magnetic core 10 and the busbar 30 for current detection while keeping them from coming into contact with each other. Furthermore, the second holding portion 44 may be fitted into a gap between the magnetic core 10 and the Hall element 20 disposed in the gap portion 12 of the magnetic core 10, thereby holding the magnetic core 10 and the Hall element 20 while keeping them from coming into contact with each other.

Furthermore, the casing main body 41 and the cover member 42 respectively may have slots 45 through which the second portions 32 at both ends of the busbar 30 for current detection are inserted from the inner side to the outer sides. In a state where one of the second portions 32 in the busbar 30 for current detection that penetrates through the hole portion 11 of the magnetic core 10 has been inserted through the slot 45 of the casing main body 41, the first holding portions 43 and the second holding portion 44 of the casing main body 41 may hold, in a fixed positional relationship, the magnetic core 10, the Hall element 20, and the busbar 30 for current detection while keeping them from coming into contact with each other.

Furthermore, the cover member 42 may be attached to the casing main body 41 holding the magnetic core 10, the Hall element 20, and the busbar 30 for current detection such that the cover member 42 covers the opening portion of the casing main body 41 while sandwiching the electronic circuit board 50 therebetween. At that time, the other second portion 32 in the busbar 30 for current detection may be inserted through the slot 45 of the cover member 42 from the inner side to the outer side, and, thus, the electronic circuit board 50 may be sandwiched between the casing main body 41 and the cover member 42.

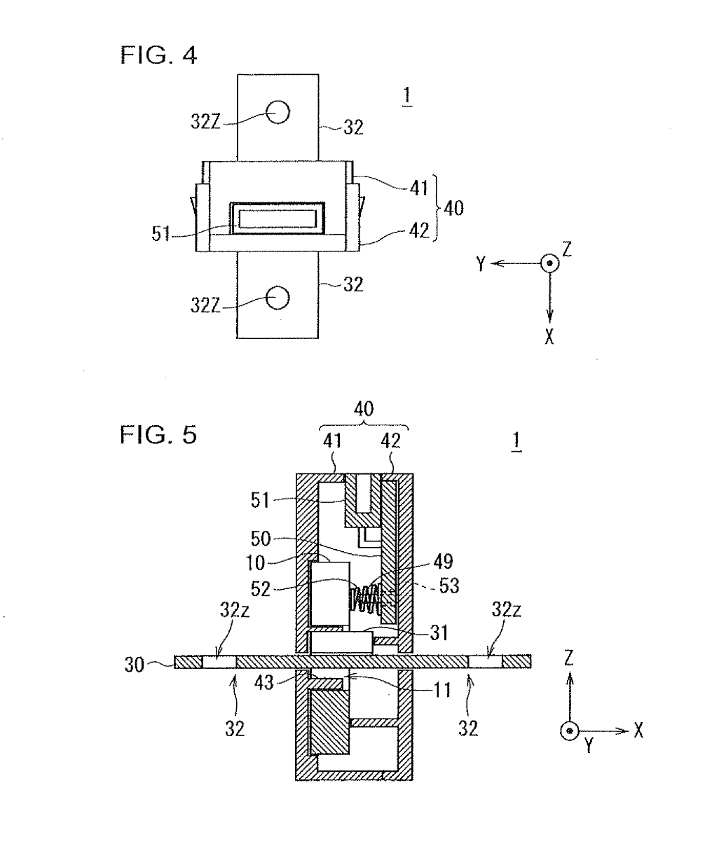

FIGS. 4 and 5 are a plan view and a cross-sectional view of the current detector 1 in which the casing main body 41 and the cover member 42 have been combined with each other. Note that, in FIG. 5, the Hall element 20 is not shown for the sake of convenience.

As shown in FIGS. 4 and 5, when the electronic circuit board 50 is sandwiched between the casing main body 41 and the cover member 42, the connector 51 mounted on the electronic circuit board 50 may be held in a state where it is fitted to a cut-out portion 46 formed in the casing main body 41. Furthermore, the casing main body 41 and the cover member 42 sandwich the magnetic core 10 and the electronic circuit board 50 therebetween in a state where the free end of the coil spring 52 that has been fixed to the electronic circuit board 50 elastically biases the magnetic core 10.

Furthermore, the casing main body 41 and the cover member 42 may be provided with lock mechanisms 47 and 48 that hold the casing main body 41 and the cover member 42 such that they are combined with each other. The lock mechanisms 47 and 48 shown in FIG. 1 may be respectively configured as a catch portion 47 formed so as to project from a side face of the casing main body 41 and a frame portion 48 in the shape of a loop on a side face of the cover member 42. When the catch portion 47 of the casing main body 41 is fitted to the hole defined by the frame portion 48 of the cover member 42, the casing main body 41 and the cover member 42 may be held in a state where they are combined with each other. In this manner, the insulating casing 40 preferably holds, in a fixed positional relationship, the magnetic core 10, the busbar 30 for current detection, and the electronic circuit board 50 on which the Hall element 20 has been mounted, in a state where the coil spring 52 elastically biases the magnetic core 10. In the current detector 1, a conductor that is disposed closest to the busbar 30 for current detection preferably is the magnetic core 10.

Furthermore, as shown in FIGS. 1 and 5, the internal face of the cover member 42 forming the insulating casing 40 may have a protruding portion 49 in the shape of a rod that penetrates through the through-hole 53 for the spring of the electronic circuit board 50 and extends into the internal space of the coil spring 52. Preferably, the protruding portion 49 keeps the coil spring 52 from being deflected or bent in the width direction orthogonal to the axial direction, thereby making the coil spring 52 compressible and stretchable mainly only in the axial direction. As a result, a failure in contact with the magnetic core 10 due to excessive deflection of the coil spring 52 in the width direction may be prevented from occurring.

In FIGS. 1 and 5, the axial direction of the coil spring 52 matches the X-axis direction. The internal face of the cover member 42 may have, in addition to the rod-like protruding portion 49, other protruding portions for positioning components that are accommodated in the insulating casing 40, but the protruding portions other than the rod-like protruding portion 49 are not shown in FIG. 1.

Furthermore, as shown in FIG. 4, the casing main body 41 and the cover member 42 (the insulating casing 40) preferably cover and hold the magnetic core 10, the first portion 31 of the busbar 30 for current detection, and the Hall element 20 in a state where the portions (terminal portions) of the second portions 32 of the busbar 30 for current detection in which the holes 32Z are formed and the connector 51 of the electronic circuit board 50 are exposed to the outside.

In the exemplary embodiment of the current detector 1 described above, the magnetic core 10 disposed closest to the busbar 30 for current detection may be electrically connected via the coil spring 52 to the ground pattern on the electronic circuit board 50. Furthermore, the ground pattern on the electronic circuit board 50 may be electrically connected to a ground conductor such as a vehicle body, via the grounding electrical wire connected via the connector 51. Accordingly, when a high voltage is generated in the busbar 30 for current detection due to a static electrical charge or the like, the high-voltage electricity flows from the busbar 30 for current detection via the magnetic core 10, the coil spring 52, and the ground pattern on the electronic circuit board 50 to the ground conductor. A surge suppression circuit may be mounted on the electronic circuit board 50 in order to suppress surges between the electronic components including the Hall element 20 and the ground pattern.

Accordingly, use of the current detector 1 can prevent electronic components from being damaged by a high voltage flowing from the busbar 30 for current detection. Furthermore, according to the current detector 1, since there is no need to ensure a large space for allowing an insulating member to electrically shield the electronic components including the Hall element 20 from the busbar 30 for current detection, it is possible to reduce the size of the current detector.

According to the exemplary embodiments of the current detector 1, since the coil spring 52 that electrically connects the magnetic core 10 and the ground pattern on the electronic circuit board 50 may be elastically deflected, the electrical contact state between the magnetic core 10 and the ground pattern on the electronic circuit board 50 is stable, and the physical load that acts on the magnetic core 10 can be made small. Moreover, since the coil spring 52 may press the magnetic core 10 and the electronic circuit board 50 against the insulating casing 40, the magnetic core 10 and the electronic circuit board 50 held by the insulating casing 40 may be prevented from wobbling.

In particular, when the coil spring 52 is used, the force of the spring member that elastically biases the magnetic core 10 is more stable than when another type of spring member such as a leaf spring is used, and, thus, the electrical connection state between the magnetic core 10 and the ground pattern on the electronic circuit board 50 tends to be more stable. It will be appreciated that other spring members such as a leaf spring connected to the ground pattern on the electronic circuit board 50 may be used instead of the coil spring 52.

Furthermore, the exemplary embodiments of the current detector 1 in which the magnetic core 10, the busbar 30 for current detection, the Hall element 20, and the electronic circuit board 50 are held in a fixed positional relationship by the insulating casing 40 can be easily attached to pre-installed busbars that are located in front of and behind the current detector 1.

### LIST OF REFERENCE NUMERALS

1 Current detector
8 Screw
9 Another busbar
10 Magnetic core
11 Hole portion
12 Gap portion
20 Hall element
21 Terminal
30 Busbar for current detection
30Y Metal member
31 First portion
32 Second portion (terminal portion)
32Z Hole
34 Slit
40 Insulating casing
41 Casing main body
42 Cover member
43 First holding portion
44 Second holding portion
45 Slot
47 Catch portion (lock mechanism)
48 Frame portion (lock mechanism)
49 Protruding portion
50 Electronic circuit board
51 Connector
52 Coil spring (spring member)
53 Through-hole for spring

1. A current detector comprising:
a magnetic core comprising two ends, the two ends facing each other across a gap portion, is the magnetic core being formed in one piece so as to surround a hole portion, through which a busbar, capable of allowing a current to flow, the busbar penetrating through the hole portion, and
a magneto-electric conversion element that is disposed in the gap portion and that detects changes in the magnetic flux of a current that flows through the hole portion, the magneto-electric conversion element comprising:
an electronic circuit board,
a circuit for processing a detection signal of the magneto-electric conversion element mounted on the electronic circuit board; and
a spring member, the spring member being made of a conductor and electrically connected to a ground pattern on the electronic circuit board, is the spring member being supported on the electronic circuit board and in contact with the magnetic core.

2. The current detector according to claim 1, further comprising:
a casing made of an insulating member, the casing positioning, the magnetic core, the busbar, and the electronic circuit board in a fixed relationship, wherein the spring member elastically biases the magnetic core.

3. The current detector according to claim 2, wherein the spring member is a coil spring having one end fixed to the electronic circuit board.

4. The current detector according to claim 3,
wherein a through-hole is formed through the electronic circuit board, and the through hole communicating with an internal space of the coil,
a protruding portion formed on the casing, the protruding portion being in a shape of a rod that penetrates through the through hole of the electronic circuit board and extending into the internal space of the coil spring.
